(19) United States
(12) Patent Application Publication
(10) Pub. No.: US 2008/0112222 A1
(43) Pub. Date: May 15, 2008

(54) NON-VOLATILE SEMICONDUCTOR MEMORY DEVICE

(75) Inventor: Masanobu Shirakawa, Fujisawa-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/935,562

(22) Filed: Nov. 6, 2007

(30) Foreign Application Priority Data
Nov. 14, 2006 (JP) 2006-307692

(51) Int. Cl. G11C 16/04

(52) U.S. Cl. 365/185.03; 365/185.09

(57) ABSTRACT

A non-volatile semiconductor memory device includes: a memory chip configured to be electrically rewritable and store such multi-level data as being defined by n-bits/cell (where n≧2); and a memory controller configured to control read and write of the memory chip, wherein the operation mode of the memory chip is changed from n-bits/cell to m-bits/cell (where m<n) when the number of late-generated defective areas is over a certain threshold value.

### CROSS-REFERENCE TO RELATED APPLICATION

This application is based on and claims the benefit of priority from the prior Japanese Patent Application No. 2006-307692, filed on Nov. 14, 2006, the entire contents of which are incorporated herein by reference.

### BACKGROUND OF THE INVENTION

1. Field of the Invention

This invention relates to a non-volatile semiconductor memory device serving for storing multi-level data.

2. Description of the Related Art

A NAND-type flash memory is known as one of electrically rewritable and non-volatile semiconductor memories (EEPROMs). In the NAND-type flash memory, multiple memory cells are connected in series in such a manner that adjacent two memory cells share a source/drain region. Therefore, the unit cell area is small, and it is easy to increase the memory capacity.

Recently, in the many kinds of mobile devices, there is a great demand for the NAND-type flash memory for storing music data and image data. Under this situation, to make the memory store data with a greater capacity, it becomes necessary to use a multi-level data storage scheme, which stores multiple bits per cell. Therefore, there have already been provided many kinds of multi-level data storage schemes (for example, refer to JP-A-2001-93288).

In the NAND-type flash memory, in which data write is performed page by page, there is usually a limit to the number of write operations. Therefore, as the memory is used, the number of write-impossible cells becomes large. In case some defects are generated in a page, if the number is in a certain range, the defects may be relieved with an ECC system. However, the defect number is over a certain value (permissible defect number), it becomes impossible to relieve the defective memory with the ECC system.

In consideration of the above-described memory block including a relief-impossible page, there has already been provided such an access-control scheme that the memory controller automatically skips the block as a late-generated bad block (see, JP-A-2005-285184). This technology is effective for reducing the address management load of a host device.

In addition, to achieve the access-control described above, there has been provided such a technology that bad block flag latches are disposed in the row decoder, and a bad block flag is set in a corresponding flag latch when a bad block is late-generated (refer to JP-A-2002-133894).

### SUMMARY OF THE INVENTION

According to an aspect of the present invention, there is provided a non-volatile semiconductor device including:

a memory chip configured to be electrically rewritable and store such multi-level data as being defined by n-bits/cell (where n≧2); and

a memory controller configured to control read and write of the memory chip, wherein

the operation mode of the memory chip is changed from n-bits/cell to m-bits/cell (where m<n) when the number of late-generated defective areas is over a certain threshold value.

According to another aspect of the present invention, there is provided a non-volatile semiconductor device including:

a memory chip configured to be electrically rewritable and store such multi-level data as being defined by n-bits/cell (where n≧2), the memory chip having a management data area, in which late-generated bad block information is written; and

a memory controller configured to control read and write of the memory chip, wherein

the late-generated bad block information in the memory chip is read out and transferred to the memory controller at a power-on time, and wherein

the memory controller makes the memory chip change the operation mode from n-bits/cell to m-bits/cell (where m<n) when the number of late-generated bad blocks is detected over a certain threshold value.

### BRIEF DESCRIPTION OF THE DRAWINGS

FIG. 1 shows a configuration of a NAND-type flash memory in accordance with an embodiment of the present invention.

FIG. 2 shows the memory cell array of the flash memory.

FIG. 3 shows a data threshold distribution and a write method of the flash memory which is in a 4-value mode.

FIG. 4 shows a data threshold distribution and a write method of the flash memory which is in a 8-value mode.

FIG. 5 shows a basic method for dealing with the late-generated block defects.

FIG. 6 shows a power-on reset operation.

FIG. 7 is a diagram for explaining the mode change and address change performed in the power-on reset operation.

FIG. 8 is a graph showing that the life span is improved by the mode change from 4-value mode to binary mode.

FIG. 9 shows a power-on reset operation in accordance with another embodiment.

FIG. 10 shows another embodiment applied to a digital still camera.

FIG. 11 shows the internal configuration of the digital still camera.

FIGS. 12A to 12J show other electric devices to which the embodiment is applied.

### DETAILED DESCRIPTION OF THE EMBODIMENTS

Illustrative embodiments of this invention will be explained with reference to the accompanying drawings below.

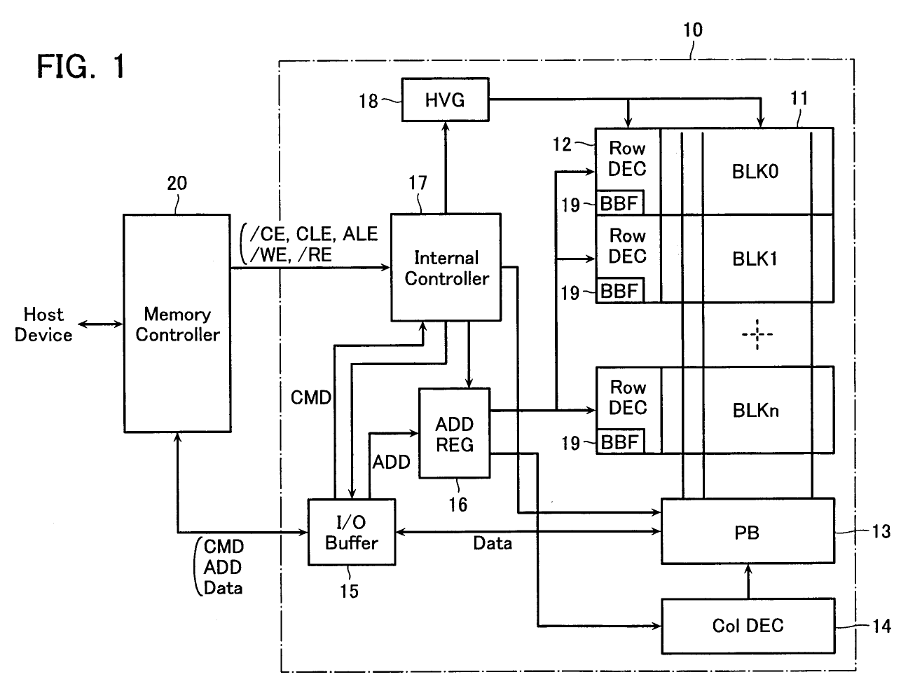

FIG. 1 shows a NAND-type flash memory in accordance with an embodiment. Flash memory chip 10 is packaged together with an external memory controller 20 for controlling it.

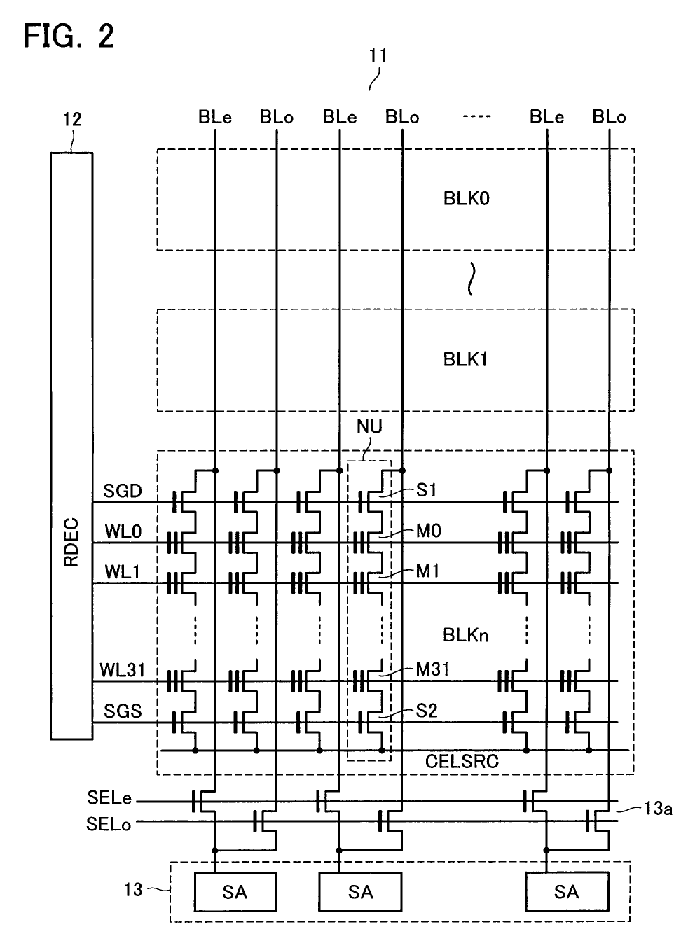

Flash memory chip 10 has cell array 11, row decoder 12 for selecting a word line thereof, page buffer 12 coupled to a bit line and used for reading and writing a page data and column decoder 14 for selecting a column. The cell array 11 is, as shown in FIG. 2, formed of multiple NAND cell units (or NAND strings) NU arranged therein.

The NAND cell unit NU has a plurality of electrically rewritable and non-volatile memory cells MC0-MC31 connected in series. Disposed at the both ends of the NAND cell unit NU are select gate transistors S1 and S2, which are used for coupling the unit to a bit line BL and a common source line CELSRC, respectively.

Control gates of the memory cells MC0-MC31 are coupled to different word lines WL0-WL31, respectively, and gates of the select gate transistors S1 and S2 are coupled to select gate lines, respectively, which are disposed in parallel with the word lines.

A set of NAND cell units sharing the word lines is defined as a block, which serves as a data erase unit. As shown in FIGS. 1 and 2, multiple blocks, BLK0-BLKn, are arranged in the bit line direction.

FIG. 2 shows such a case that an even numbered bit line BLe and an adjacent odd numbered bit line BLo share a sense amplifier SA. That is, either one of the even bit line BLe and odd bit line BLo is selected by a bit line select circuit 13a to be coupled to the sense amplifier SA.

In this case, a range selected by all even bit lines and a word line is defined as a physical page (i.e., even page), which is subject to collective read or write while another range selected by all odd bit lines and a word line is defined as another physical page (i.e., odd page), which is subject to collective read or write. The page buffer 13 is formed to have sense amplifiers SA, which are able to store one page read or write data.

Internal controller 17 receives many kinds of control signals (chip enable signal /CE, command latch enable signal CLE, address latch enable signal ALE, write enable signal /WE, read enable signal /RE and the like), and command CMD supplied from the external memory controller 20, and controls read/write/erase of the cell array 11.

In this embodiment, this internal controller 17 has a sequencer function for performing four-level data write/read and another sequencer function for performing binary data write/read, and these sequencer functions are exchangeable with an instruction from the external controller 20. Usually, the sequencer function for four-level data is set to be effective.

To generate high voltages necessary for read, write and erase operations, there is prepared a high voltage generation circuit 18, which is also controlled by the internal controller 17.

It is effective to contain a part of (or a main part of) the functions of the internal controller 17 in the external memory controller 20. For example, it is permissible to limit the functions of the internal controller 17 to voltage control, timing control, ROM fuse data reading control of the cell array 11 at a power-on time and the like, and install the write sequencer function of the memory chip 10 and the like in the memory controller 20 as software data.

In this case, the software is written in a ROM area of the cell array 11, and read out at a power-on reset time to be transferred to and installed in the external memory controller 20.

Address ADD, command CMD and data Data are input via I/O buffer 15. Address ADD is supplied to row decoder 12 and column decoder 14 via address register 16 while command CMD is input to the controller 17 and decoded therein.

The row decoder 12 has latches 19 for storing bad block flags (BBF), which are used for access-inhibiting for bad blocks.

In this embodiment, the flash memory stores multi-level data defined by multi-bits/cell.

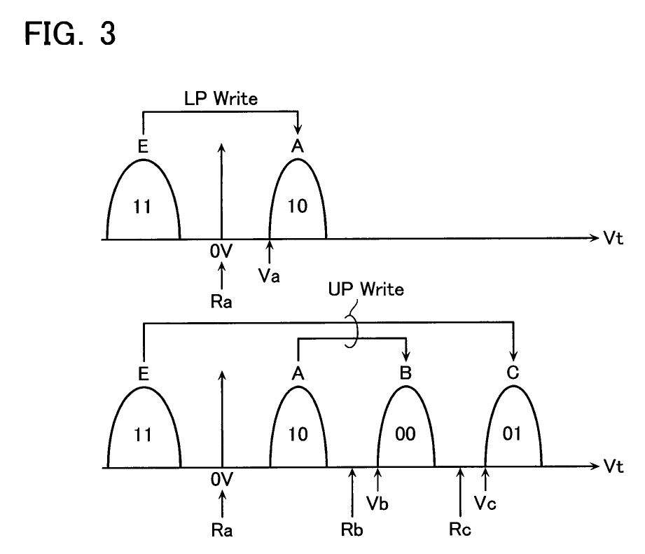

FIG. 3 shows a data threshold distribution and a data bit assignment in case of a four-level data storage scheme of 2-bits/cell.

Erase state E is a negative threshold state while A, B and C are write states with positive threshold voltages. 4-level data is represented by (UP, LP), where UP is an upper page bit; and LP a lower page bit. In this example, the 4-level data is defined as follows: E=(1, 1); A=(1, 0); B=(0, 0); and C=(0, 1).

To write the 4-level data, lower page (LP) write is firstly performed. In this LP write sequence, “0” data write is selectively performed for cell(s) in the erase state E, so that data state A is written into the cell(s), the lower limit of which is defined by verify voltage Va.

Following it, “0” write defined as upper page (UP) write is selectively performed for increasing the threshold voltages of cells with data states E and A, and data states B and C are obtained, lower limits of which are defined by verify voltages Vb and Vc, respectively. In detail, the write pulse applications for data states B and C are performed simultaneously; and write-verify operations thereof are performed independently from each other with two steps of verify voltages Vb and Vc, respectively.

The 4-level data written as described above may be read out as follows: the upper page data is read out with read voltage Rb set between data states A and B; and the lower page data is read out with two steps, in which read voltages Ra and Rc are set between E and A, and between B and C, respectively.

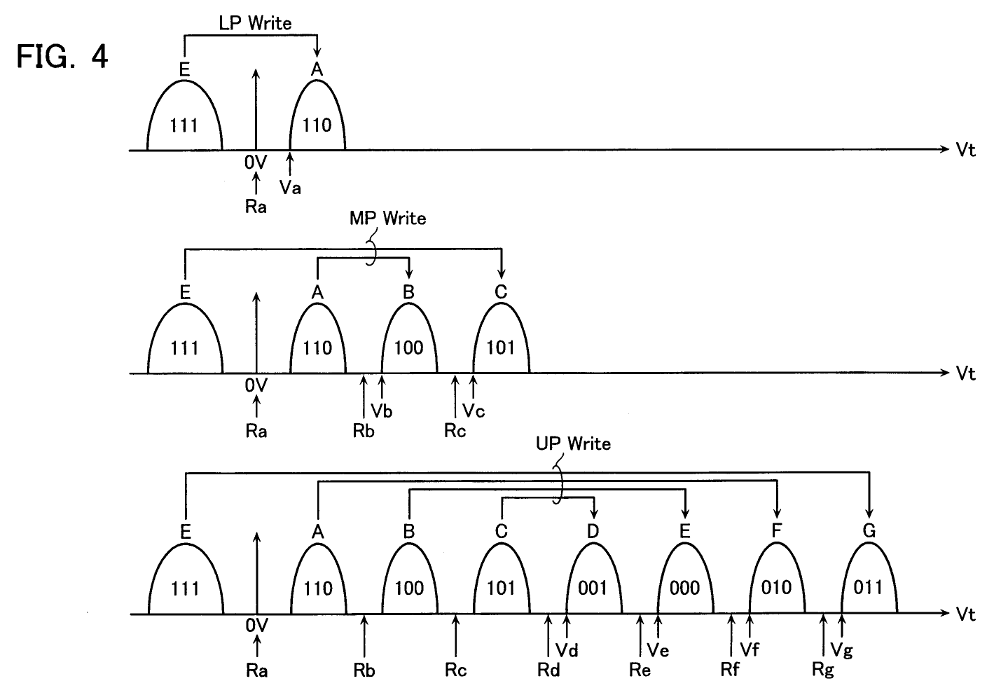

FIG. 4 shows a data threshold distribution and a bit assignment in an eight-level data storage scheme, in which the same scheme is adapted as described in the 4-level data storage scheme.

8-level data is expressed by (UP, MP, LP), where UP is upper page data; MP middle page data; and LP lower page data, based on eight data states E, A, B, C, D, E, F and G as shown in the lowest column in FIG. 4.

Firstly, in accordance with the lower page (LP) write, cells of data state E defined as an erase state are selectively set at data state A defined by verify voltage Va.

Following it, in accordance with the middle page (MP) write, cells of data states E and A are selectively set at data states C and B defined by write verify operations with verify voltages Vc and Vb, respectively.

Similarly, in accordance with the upper page (UP) write, cells of data states E, A, B and C are selectively set at data states G, F, E and D defined by write verify operations with verify voltages Vg, Vf, Ve and Vd, respectively.

Assuming that the above-described multi-level data storage schemes are used, in this embodiment, two dealing methods will be adapted for solving the problem of the late-generated defects.

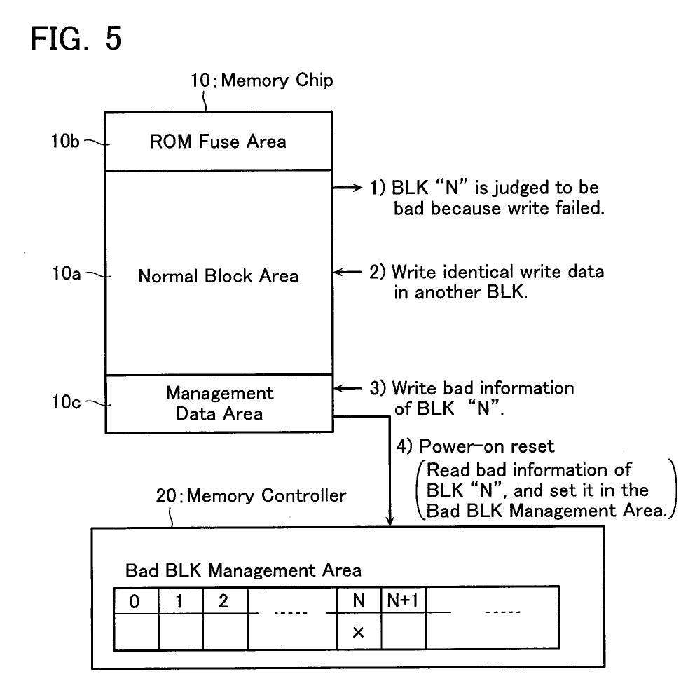

A first dealing method will be explained with reference to FIG. 5.

Note here that the memory chip 10 has, as shown in FIG. 5, normal block area 10a, ROM fuse area 10b and management data area 10c. In these areas, the normal block area 10a is a user's area, in which users are leaved to usually read and write data.

ROM fuse area 10b is an initial set-up data area, in which program data of the internal controller 17 and external memory controller 20, various trimming data, defective address data and the like are written at a product shipping time. These data are automatically read out at a power-on time, and the respective program data are set in the internal controller 17 and memory controller 20; and trimming data and defective address data are stored in the corresponding data registers (not shown) to be supplied for controlling data read/write. In detail, the defective address data is used for controlling the defective address replacement.

The management data area 10c is prepared for storing late-generated bad block information, mode changing information of a 4-level mode and a binary mode as described later, a logical/physical address transformation table and the like. The logical/physical address transformation table is supplied to the memory controller 20 for selecting a physical address of the flash memory chip 10 in such a scheme that a host device accesses the flash memory chip 10 only with logical addresses without managing the physical addresses.

As shown in FIG. 5, assume that 1) block N in the flash memory is judged to be bad because it failed in write. At this time, 2) write the identical write data into another block (i.e., a spare block). Further, 3) write information indicating that block N is bad into the management data area 10c.

Then, as a power-on reset operation at a power-on time of the flash memory, not only data in the ROM fuse data area 10b but also 4) the bad block information in the management data area 10c are read out. The read out bad block information is transferred to the memory controller 20, and data indicating that block N is bad is written in a bad block management area therein.

As a result, when the host device accesses the flash memory, it becomes possible that the memory controller 20 accesses the memory chip in such a manner as to skip the bad block N. Explaining in detail, to access the flash memory, the host device transmits a command and a logical address, and write data if in a write mode. The memory controller 20 selects a physical address of the flash memory based on the address transformation table and performs read/write. In case of write, logical/physical address transformation table will be rewritten in accordance with the selected physical address.

The above-described bad block information is reflected on the logical/physical address transformation table, and makes the memory controller automatically skip the bad block.

However, even if adapting the above-described first dealing method only, there is a limit to the reliability and lifetime of the flash memory. Since it is required in general of the multi-level memory to control narrow data threshold distributions, the more the number of accessing, the more the number of bad blocks, which are impossible to write data due to declining of the cell performance.

In consideration of the above-described situation, as a second dealing method in this embodiment, when the number of late-generated bad blocks reaches a certain value, the operation mode of the memory chip is switched or changed from the multi-level mode to a binary mode. This is a result of the following consideration: even if the number of write-impossible blocks increases, using the lower page data and the upper page data of four-level data as binary data, there are many usable areas.

Explaining in detail, assuming that the block number of the normal block area 10a is Nmax, when the bad block number is, for example, over Nmax/2, the operation mode is switched.

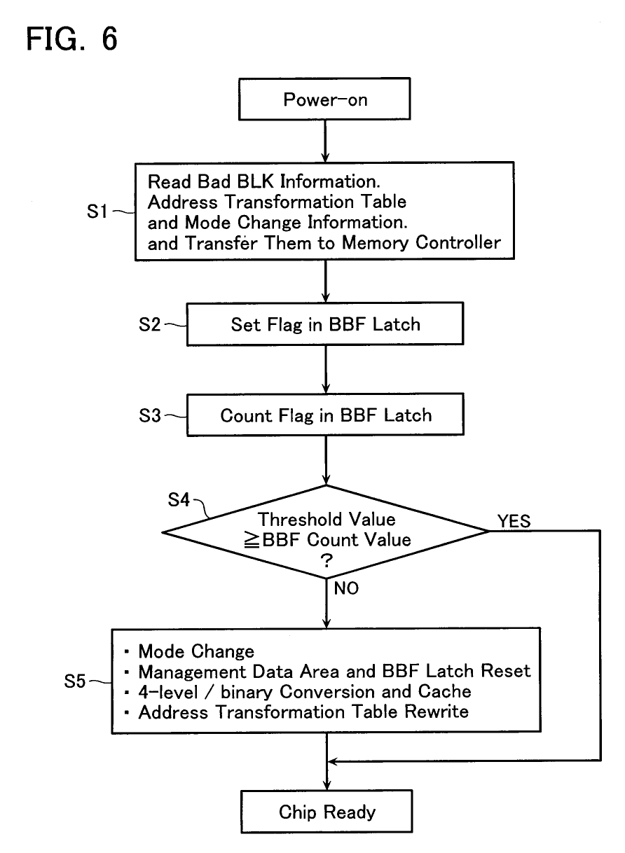

In consideration of the above-described first and second dealing methods, a power-on reset operation in this embodiment will be explained with reference to FIG. 6 below.

When the power is switched on, in addition to the initial set-up operation for read data of the ROM fuse area 10b as described above, bad block information, address transformation table and mode change information are read out from the management data area 10c, and these are set in the memory controller 20 (step S1).

While, the memory controller 20 sets a flag(s) in the corresponding BBF latch(es) 19 in the row decoder 12 shown in FIG. 1, which designates that the corresponding block is bad (step S2).

Further, the memory controller 20 makes the memory chip 10 count the flags in the BBF latches attached to the row decoder 12 (step S3). That is, the memory chip 10 has such the counting function, and counts the bad block number based on the direction from the memory controller 20 to output the count result to the memory controller 20.

The memory controller 20 judges whether the number of bad blocks is under the threshold value or not (step S4). If YES, the chip is set in a ready state without changing the operation mode to wait the following command. When read or write command is sent from the memory controller 20, read or write will be performed in accordance with the 4-level mode.

If the judgment result at step S4 is NO, the 4-level mode is switched to the binary mode (step S5). Explaining in detail, set the mode changing information of 4-level/binary; transform 4-level data that have been written to binary data, and cache them into different physical pages; erase the bad block information of the management data area 10c in the memory chip 10, and reset the BBF latches 19 in the row decoder 12. Even if the four-level mode is not adaptable in the bad block, the block may be usable as a normal one for the binary mode.

Data transformation of 4-level/binary and caching the transformed data are performed in such a manner than the upper page (UP) data read and lower page (LP) data read are sequentially performed in accordance with a 4-level data read method, and these read data are rewritten back to different physical pages from each other. Explaining in detail, the upper page data and lower page data are basically written to be superimposed on each other in a physical page, and these may be read out with read voltages shown in FIG. 3 in such a way that the upper page data is read out with read voltage Rb set between data states A and B; and the lower page data is read out via two read steps with read voltage Ra set between data states E and A, and read voltage Rc set between data state B and C. These UP read data and LP read data are written as binary data in accordance with the same condition as that of the LP write, for example, shown in FIG. 3, or in accordance with another binary data write condition, into (a) the late-generated bad block, or (b) a spare block. Preferably, the former (a) should be given priority.

For example, the UP data of 4-level data written in the cache source block is read out and then written as binary data into a block with the least address in the late-generated bad blocks registered in the controller; and successively the lower page is read out and then written as binary data into another block with the second least block address. As a result of the above-described data caching, it is required of the controller to rewrite the management data area. That is, data in the cache source block will be erased because it becomes unnecessary. As a result, the cache source block will be used as a spare block hereinafter.

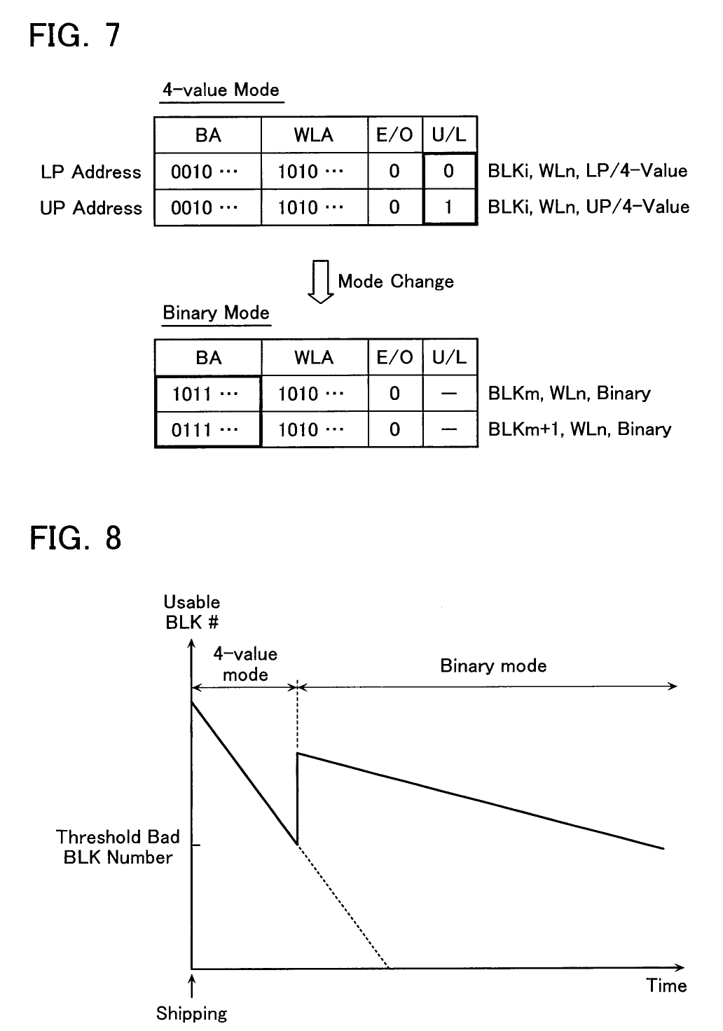

FIG. 7 shows the address change in accordance with the data rewrite taken with the 4-level/binary transformation. As shown in FIG. 7, in the 4-level mode, there is only such a difference between the UP address and LP address that the designating bit (U/L) of the upper page/lower page is “0”/“1” as shown in a thick frame. That is, block address (BA) bits, word line select address (WLA) bits and even page(E)/odd page(O) designating bits are the same in the UP address and LP address, and it designates that these UP data and LP data are written as being superimposed on each other in a block BLKi and a word line WLn therein.

These LP data and UP data of the 4-level mode are, as shown in the binary mode table shown in FIG. 7, cached and written as binary data in such a manner that the former is written into a word line WLn in a block BLKm while the latter is written into the same numbered word line WLn in another block BLKm+1. As shown in a thick frame, the blocks BLKm and BLKm+1 have different block addresses (1011 . . . ) and (0111 . . . ), respectively. After the mode switching, the designating bit (U/L) of the upper page/lower page becomes unnecessary.

In accordance with the result of the 4-level/binary data transformation and the write back operation, it is also required of the logical/physical address transformation table in the memory controller 20 to be rewritten. In addition, according to the mode change information is set, the sequencer function of the internal controller 17 or the external memory controller 20 is also exchanged for the purpose of accessing hereinafter.

The above-described operations in the step S5 will be automatically performed by the memory controller 20 based on the result of the bad block counting.

Note here that rewritten address transformation table and mode change information are written into the management data area 10c of the memory chip 10 when the power supply becomes off.

As a result, with respect to the following read/write access from the host, the memory controller 20 executes read/write of binary data corresponding to the lower page data shown in FIG. 3.

By use of the above-described operation mode change, as shown in FIG. 8, the life span of the flash memory will be substantially prolonged. That is, in case the 4-level data storage scheme is continuously used as it is, the number of usable blocks may be abruptly decreased. By contrast, if it is changed to the binary data storage mode, not only there is a possibility that blocks dealt as bad ones become usable, but also the data threshold control becomes easy, and it will lead to the reduction of the defect generation rate.

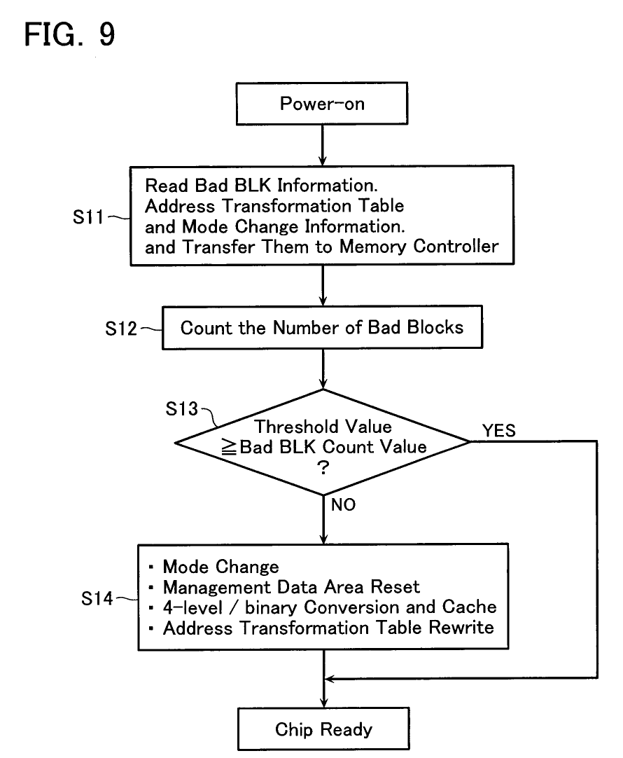

FIG. 9 shows an example of the power-on reset operation of the flash memory in accordance with another embodiment.

When the power is switched on, in addition to the initial set-up operation for read data of the ROM fuse area 10b as described above, bad block information, address transformation table and mode change information are read out from the management data area 10c, and these are set in the memory controller 20 (step S11). This is the same as in the above-described embodiment.

Then, without setting the late-generated bad block flag in the BBF latch 12 of the row decoder, count the number of late-generated bad blocks based on data in the bad block management area by use of the counting function installed in the memory controller 20 (step S12).

Following it, judge whether the number of bad blocks is under a threshold value or not (step S13). If YES, the chip is set in a ready state while if the judgment result is NO, the 4-level mode is changed to a binary mode (step S14).

When changing the operation mode, the bad block information in the management data area of the memory chip 10 is erased; 4-value data is read out and rewritten into binary data; and logical/physical address transformation table is rewritten. This is the same as in the above-described embodiment. There is no need of resetting the BBF latch.

According to such the method that the BBF latch is not used for information management of the late-generated bad blocks as described above, the power-on reset operation may be made simple. Further, assuming that the BBF latch is used for setting a flag with respect to a bag block detected in a wafer test before shipping, it is in need of using some means for distinguishing the bad block detected at the wafer test time from the late-generated bad block for counting the flags of BBF latches only for the late-generated bad blocks, or resetting them.

In the above-described embodiments, 4-vale data storage scheme (i.e., 2 bits/cell scheme) has been used as one of multi-level data storage schemes. However, it should be noted that this invention is effective for 2ⁿ-level data storage scheme (i.e., n-bits/cell scheme, where “n” is 3 or more).

Explaining in general, in case a multi level data storage scheme defined by n-bits/cell (n≧2) is used, the operation mode is controlled to be changed from n-bits/cell to m-bits/cell (m<n) when the number of late-generated bad blocks is over a threshold value. As a result, the product's life span and performance will be substantially improved.

Further, in case of 8-value storage scheme, it is preferred to use such a mode change scheme that 8-value mode (3-bits/cell mode) is changed to 4-value mode (2-bits/cell mode) when the number of late-generated bad blocks is over a threshold value; and then 4-value mode is changed to binary mode (1-bit/cell mode) when the number of late-generated bad blocks is over another threshold value.

[Application Devices]

As an embodiment, an electric card using the non-volatile semiconductor memory devices according to the above-described embodiments of the present invention and an electric device using the card will be described bellow.

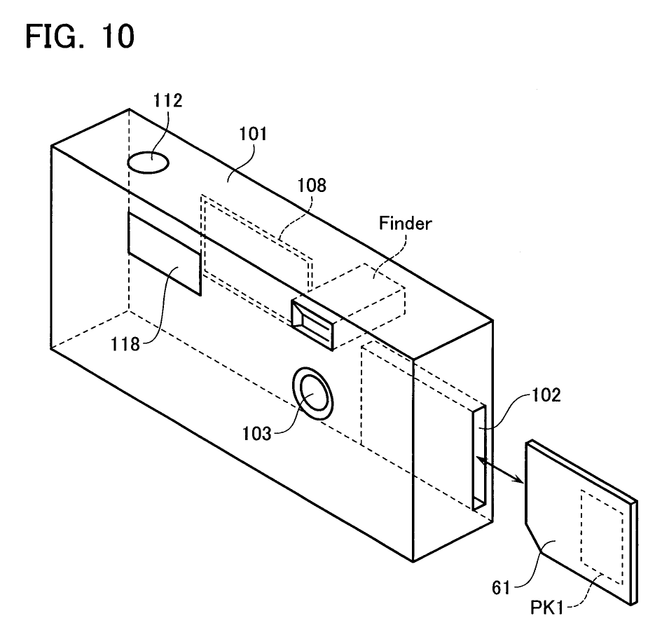

FIG. 10 shows an electric card according to this embodiment and an arrangement of an electric device using this card. This electric device is a digital still camera 101 as an example of portable electric devices. The electric card is a memory card 61 used as a recording medium of the digital still camera 101. The memory card 61 incorporates an IC package PK1 in which the non-volatile semiconductor memory device or the memory system according to the above-described embodiments is integrated or encapsulated.

The case of the digital still camera 101 accommodates a card slot 102 and a circuit board (not shown) connected to this card slot 102. The memory card 61 is detachably inserted in the card slot 102 of the digital still camera 101. When inserted in the slot 102, the memory card 61 is electrically connected to electric circuits of the circuit board.

If this electric card is a non-contact type IC card, it is electrically connected to the electric circuits on the circuit board by radio signals when inserted in or approached to the card slot 102.

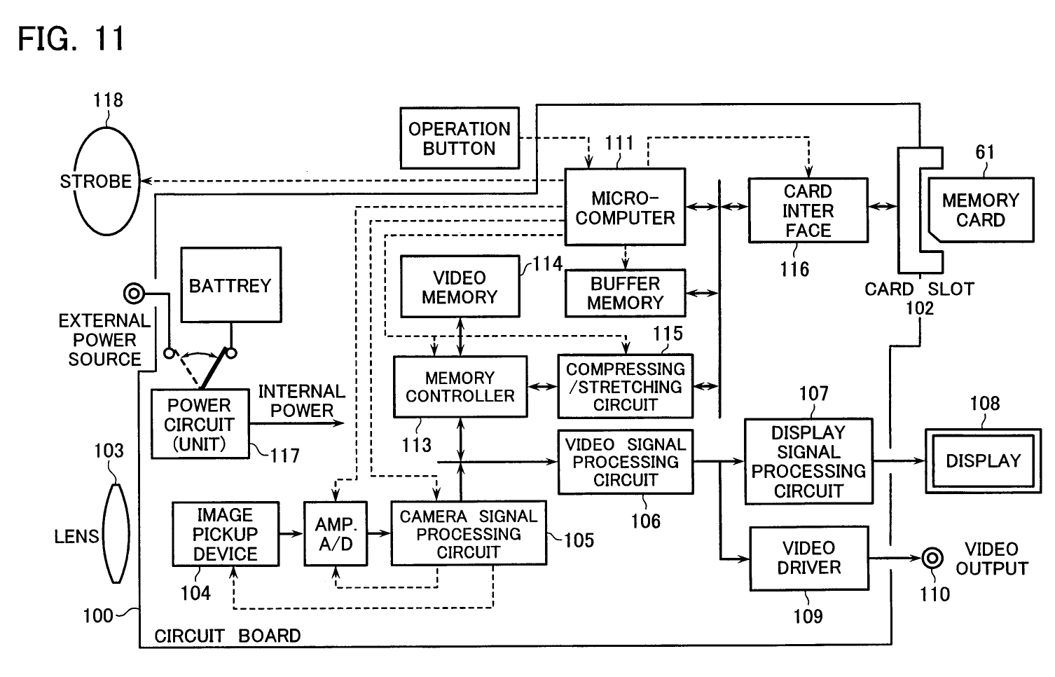

FIG. 11 shows a basic arrangement of the digital still camera. Light from an object is converged by a lens 103 and input to an image pickup device 104. The image pickup device 104 is, for example, a CMOS sensor and photoelectrically converts the input light to output, for example, an analog signal. This analog signal is amplified by an analog amplifier (AMP), and converted into a digital signal by an A/D converter (A/D). The converted signal is input to a camera signal processing circuit 105 where the signal is subjected to automatic exposure control (AE), automatic white balance control (AWB), color separation, and the like, and converted into a luminance signal and color difference signals.

To monitor the image, the output signal from the camera processing circuit 105 is input to a video signal processing circuit 106 and converted into a video signal. The system of the video signal is, e.g., NTSC (National Television System Committee). The video signal is input to a display 108 attached to the digital still camera 101 via a display signal processing circuit 107. The display 108 is, e.g., a liquid crystal monitor.

The video signal is supplied to a video output terminal 110 via a video driver 109. An image picked up by the digital still camera 101 can be output to an image apparatus such as a television set via the video output terminal 110. This allows the pickup image to be displayed on an image apparatus other than the display 108. A microcomputer 111 controls the image pickup device 104, analog amplifier (AMP), A/D converter (A/D), and camera signal processing circuit 105.

To capture an image, an operator presses an operation button such as a shutter button 112. In response to this, the microcomputer 111 controls a memory controller 113 to write the output signal from the camera signal processing circuit 105 into a video memory 114 as a flame image. The flame image written in the video memory 114 is compressed on the basis of a predetermined compression format by a compressing/stretching circuit 115. The compressed image is recorded, via a card interface 116, on the memory card 61 inserted in the card slot.

To reproduce a recorded image, an image recorded on the memory card 61 is read out via the card interface 116, stretched by the compressing/stretching circuit 115, and written into the video memory 114. The written image is input to the video signal processing circuit 106 and displayed on the display 108 or another image apparatus in the same manner as when image is monitored.

In this arrangement, mounted on the circuit board 100 are the card slot 102, image pickup device 104, analog amplifier (AMP), A/D converter (A/D), camera signal processing circuit 105, video signal processing circuit 106, display signal processing circuit 107, video driver 109, microcomputer 111, memory controller 113, video memory 114, compressing/stretching circuit 115, and card interface 116.

The card slot 102 need not be mounted on the circuit board 100, and can also be connected to the circuit board 100 by a connector cable or the like.

A power circuit 117 is also mounted on the circuit board 100. The power circuit 117 receives power from an external power source or battery and generates an internal power source voltage used inside the digital still camera 101. For example, a DC-DC converter can be used as the power circuit 117. The internal power source voltage is supplied to the respective circuits described above, and to a strobe 118 and the display 108.

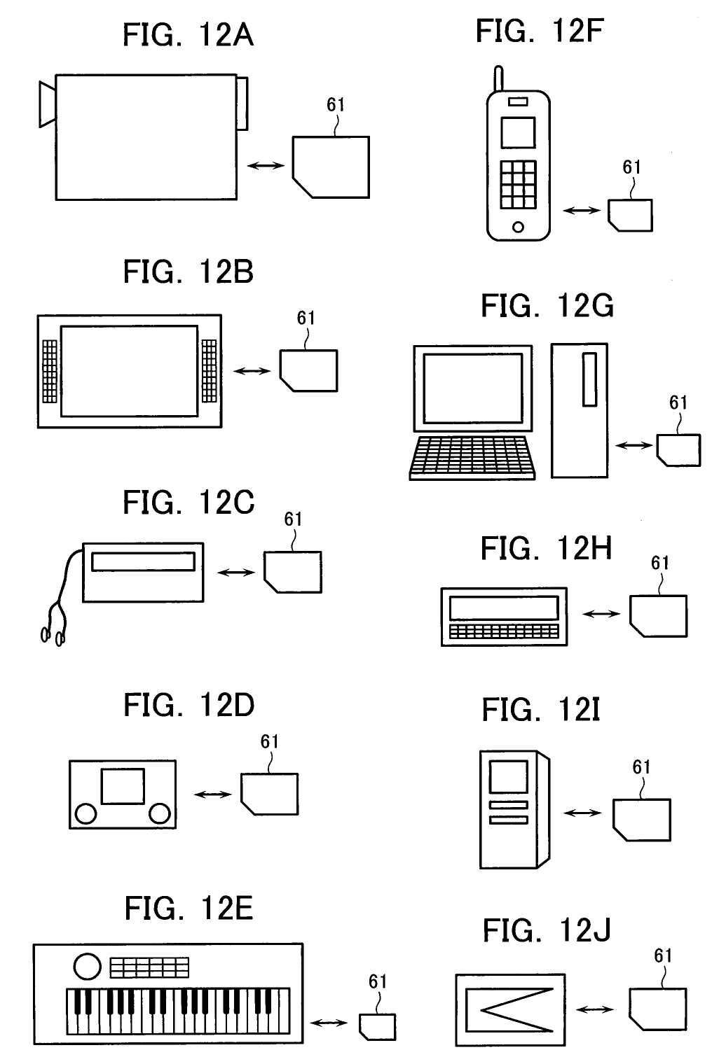

As described above, the electric card according to this embodiment can be used in portable electric devices such as the digital still camera explained above. However, the electric card can also be used in various apparatus such as shown in FIGS. 12A to 12J, as well as in portable electric devices. That is, the electric card can also be used in a video camera shown in FIG. 12A, a television set shown in FIG. 12B, an audio apparatus shown in FIG. 12C, a game apparatus shown in FIG. 12D, an electric musical instrument shown in FIG. 12E, a cell phone shown in FIG. 12F, a personal computer shown in FIG. 12G, a personal digital assistant (PDA) shown in FIG. 12H, a voice recorder shown in FIG. 12I, and a PC card shown in FIG. 12J.

This invention is not limited to the above-described embodiment. It will be understood by those skilled in the art that various changes in form and detail may be made without departing from the spirit, scope, and teaching of the invention.

What is claimed is:

1. A non-volatile semiconductor memory device comprising:
a memory chip configured to be electrically rewritable and store such multi-level data as being defined by n-bits/cell (where n≧2); and
a memory controller configured to control read and write of the memory chip, wherein
the operation mode of the memory chip is changed from n-bits/cell to m-bits/cell (where m<n) when the number of late-generated defective areas is over a certain threshold value.

2. The non-volatile semiconductor memory device according to claim 1, wherein
the memory chip contains a normal block area, in which normal read/write is performed, and a management data area, in which late-generated bad block information is written, and wherein
the bad block information in the management data area is read out to the memory controller at a power-on reset time and serves for access-controlling the memory chip hereinafter.

3. The non-volatile semiconductor memory device according to claim 1, wherein
the memory controller counts the number of late-generated bad blocks in the memory chip at a power-on reset time, and changes the operation mode of the memory chip from the n-bits/cell to the m-bits/cell when the count value is over a threshold value.

4. The non-volatile semiconductor memory device according to claim 3, wherein
the memory controller stores bad block information read from the memory chip at the power-on reset time, and counts the number of late-generated bad blocks based on the bad block information.

5. The non-volatile semiconductor memory device according to claim 1, wherein
the memory chip has flag latches for storing flags designating that the corresponding blocks are bad, and a function for counting the flags, and wherein
the memory controller directs the memory chip to count the number of late-generated bad blocks based on the flag data in the flag latches at a power-on reset time for changing the operation mode.

6. The non-volatile semiconductor memory device according to claim 1, wherein
the memory chip has basically a four-level mode defined by 2-bits/cell, and wherein
the four-level mode is changed to a binary mode defined by 1-bit/cell when the number of bad blocks in the four-level mode is over a certain threshold value.

7. The non-volatile semiconductor memory device according to claim 6, wherein
four-level data in the bad block is read out, and upper page and lower page data thereof are written as binary data together with address changes into different physical pages from each other.

8. The non-volatile semiconductor memory device according to claim 1, wherein
the memory chip has basically an eight-level mode defined by 3-bits/cell, and wherein
the eight-level mode is changed to a four-level mode defined by 2-bits/cell when the number of bad blocks in the eight-level mode is over a threshold value, and the four-level mode is changed to a binary mode defined by 1-bit/cell when the number of bad blocks in the four-level mode is over a threshold value.

9. The non-volatile semiconductor memory device according to claim 1, wherein
the memory chip has a memory cell array with NAND cell units arranged therein, each the NAND cell unit having a plurality of memory cells connected in series and select gate transistors disposed at both ends thereof.

10. A non-volatile semiconductor memory device comprising:
a memory chip configured to be electrically rewritable and store such multi-level data as being defined by n-bits/cell (where n≧2), the memory chip having a management data area, in which late-generated bad block information is written; and
a memory controller configured to control read and write of the memory chip, wherein
the late-generated bad block information in the memory chip is read out and transferred to the memory controller at a power-on time, and wherein
the memory controller makes the memory chip change the operation mode from n-bits/cell to m-bits/cell (where m<n) when the number of late-generated bad blocks is detected over a certain threshold value.

11. The non-volatile semiconductor memory device according to claim 10, wherein
the memory controller counts the number of late-generated bad blocks in the memory chip based on the late-generated bad block information transferred from the memory chip at the power-on reset time.

12. The non-volatile semiconductor memory device according to claim 10, wherein
the memory chip has flag latches for storing flags designating that the corresponding blocks are bad, and a function for counting the flags, and wherein
the memory controller directs the memory chip to count the number of late-generated bad blocks based on the flag data in the flag latches at the power-on reset time.

13. The non-volatile semiconductor memory device according to claim 10, wherein
the memory chip has basically a four-level mode defined by 2-bits/cell, and wherein
the four-level mode is changed to a binary mode defined by 1-bit/cell when the number of bad blocks in the four-level mode is over a certain threshold value.

14. The non-volatile semiconductor memory device according to claim 13, wherein
four-level data in the bad block is read out, and upper page and lower page data thereof are written as binary data together with address changes into different physical pages from each other.

15. The non-volatile semiconductor memory device according to claim 10, wherein
the memory chip has basically an eight-level mode defined by 3-bits/cell, and wherein
the eight-level mode is changed to a four-level mode defined by 2-bits/cell when the number of bad blocks in the eight-level mode is over a threshold value, and the four-level mode is changed to a binary mode defined by 1-bit/cell when the number of bad blocks in the four-level mode is over a threshold value.

16. The non-volatile semiconductor memory device according to claim 10, wherein
the memory chip has a memory cell array with NAND cell units arranged therein, each the NAND cell unit having a plurality of memory cells connected in series and select gate transistors disposed at both ends thereof.
